(19) United States
(12) Patent Application Publication
(10) Pub. No.: US 2006/0220084 A1
(43) Pub. Date: Oct. 5, 2006

(54) Magnetoresistive effect element and method for fabricating the same

(75) Inventors: Shinjiro Umehara, Kawasaki (JP); Hiroshi Ashida, Kawasaki (JP); Masashige Sato, Kawasaki (JP); Kazuo Kobayashi, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/167,279

(22) Filed: Jun. 28, 2005

(30) Foreign Application Priority Data
Mar. 18, 2005 (JP) 2005-080311

(51) Int. Cl. H01L 29/94

(52) U.S. Cl. 257/296

(57) ABSTRACT

The magnetoresistive effect element comprises a first ferromagnetic layer 50, a nonmagnetic layer 52 formed on the first ferromagnetic layer 50, a second ferromagnetic layer 54 formed on the nonmagnetic layer 52, and a sidewall insulating film 64 formed on the side wall of the second ferromagnetic layer 54. The end of the first ferromagnetic layer 50 is aligned with the end of the sidewall insulating film 64. Whereby the disalignment between the first ferromagnetic layer and the second ferromagnetic layer can be prevented.

### CROSS-REFERENCE TO RELATED APPLICATIONS

This application is based upon and claims the benefit of priority from the prior Japanese Patent Application No. 2005-080311, filed on Mar. 18, 2005, the entire contents of which are incorporated herein by reference.

### BACKGROUND OF THE INVENTION

The present invention relates to a magnetoresistive effect element, more specifically, a magnetoresistive effect element whose resistance value is varied depending on magnetization directions of the magnetic layers, and a method for fabricating the magnetoresistive effect element.

Recently, as a rewritable nonvolatile memory, a magnetic random access memory (hereinafter called an MRAM) including magnetoresistive effect elements arranged in a matrix is noted. The MRAM memorizes information by using combinations of magnetization directions of two magnetic layers and reads memorized information by detecting resistance changes (i.e., current changes or voltage changes) between when magnetization directions of the magnetic layers are parallel with each other and when magnetization directions of the magnetic layers are antiparallel with each other.

As magnetoresistive effect elements forming the MRAM, a magnetic tunnel junction (hereinafter called an MTJ) element is known. The MTJ element includes two ferromagnetic layers laid one on another with a tunnel insulating film formed therebetween and utilizes the phenomena that the tunnel current flowing between the magnetic layers via the tunnel insulating film changes depending on relationships of magnetization directions of the two ferromagnetic layers. That is, the MTJ element has low resistance when the magnetization directions of the two ferromagnetic layers are parallel with each other and has high resistance when the magnetization directions are antiparallel with each other. These two states are related to data “0” and data “1” to thereby use the MTJ element as a memory device.

The structure of the conventional magnetoresistive effect elements will be explained with reference to FIGS. 10A and 10B.

As shown in FIG. 10A, an antiferromagnetic layer 102 of an antiferromagnetic material is formed on a lower electrode layer 100. On the antiferromagnetic layer 102, a pinned magnetic layer 104 of a ferromagnetic material is formed. On the pinned magnetic layer 104, a tunnel insulating layer 106 is formed. On the tunnel insulating layer 106, a free magnetic layer 108 of a ferromagnetic material is formed. On the free magnetic layer 108, a cap layer 110 of a non-magnetic layer is formed. The cap layer 110, the free magnetic layer 108, the tunnel insulating layer 106, the pinned magnetic layer 104 and the antiferromagnetic layer 102 are processed in the same pattern and form the MTJ element 112.

The layer structure of the magnetoresistive effect element shown in FIG. 10B is the same as that of the magnetoresistive effect element shown in FIG. 10A. The former is different from the magnetoresistive effect element shown in FIG. 10A is that the pinned magnetic layer 14 and the free magnetic layer 108 are processed in patterns different from each other.

The related arts are disclosed in, e.g., Reference 1 (Masamichi Matsuura, “Sputter and etching system for the mass-production of MRAM device”, FED Review, Vol. 1, No. 26, Mar. 14, 2002, pp. 1-6) and Reference 2 (Kiyokazu Nagahara et al., “Magnetic tunnel junction (MTJ) patterning for magnetic random access memory (MRAM) process application”, Jpn. J. Appl. Phys., Vol. 42 (2003), pp. L499-L501).

### SUMMARY OF THE INVENTION

The conventional magnetoresistive effect element shown in FIG. 10A can have the device area reduced, and can be integrated. However, the edges of the pinned magnetic layer 104 and the free magnetic layer 108 are adjacent to each other, and a magnetic bias is applied due to the leakage magnetic field from the pinned magnetic layer 104. Resultantly, the magnetic field (Hfc) which changes the resistance state is shifted to often cause erroneous writing and erroneous reading. This leakage magnetic field changes depending on a processed edge configuration. Especially, when downsized, the degree of the generation of the leakage magnetic field influencing the free magnetic layer 108 becomes relatively higher. Objects staying back to the pinned magnetic layer 104 in processing the pinned magnetic layer 104 often cause electric short-circuit between the pinned magnetic layer 104 and the free magnetic layer 108.

In the conventional magnetoresistive effect element shown in FIG. 10B, the edge of the pinned magnetic layer 104 is spaced from the edge of the free magnetic layer 108, whereby the influences of the leakage magnetic field from the pinned magnetic layer 104 and the staying-back objects can be decreased. However, the large area of the pinned magnetic layer 104 is unsuitable for high integration. When the pinned magnetic layer 104 is made smaller, due to the disalignment of the free magnetic layer 108 with the pinned magnetic layer 104, the influence of the leakage magnetic field from the pinned magnetic layer 104 is changed, which often causes erroneous writing and erroneous reading.

An object of the present invention is to provide a magnetoresistive effect element which can suppress erroneous writing and erroneous reading due to the fluctuation of the leakage magnetic field from the pinned magnetic layer, and a method for fabricating the magnetoresistive effect element. Another object of the present invention is to provide a magnetic memory device of high reliability, which comprises the magnetoresistive effect element.

According to one aspect of the present invention, there is provided a magnetoresistive effect element comprising: a first ferromagnetic layer; a nonmagnetic layer formed on the first ferromagnetic layer; a second ferromagnetic layer formed on the nonmagnetic layer; and a sidewall insulating film formed on a side wall of the second ferromagnetic layer, an end of the first ferromagnetic layer being aligned with an end of the sidewall insulating film.

According to another aspect of the present invention, there is provided a method for fabricating a magnetoresistive effect element comprising the steps of: forming a first ferromagnetic layer; forming a nonmagnetic layer on the first ferromagnetic layer; forming a second ferromagnetic layer on the nonmagnetic layer; forming a cap layer of a nonmagnetic material on the second ferromagnetic layer; patterning the cap layer and the second ferromagnetic layer into a prescribed configuration; forming a sidewall insulating film on the side wall of the patterned cap layer and second ferromagnetic layer; and patterning the nonmagnetic layer and the first ferromagnetic layer with the cap layer and the sidewall insulating film as the mask.

According to another aspect of the present invention, there is provided a magnetic memory device comprising: a first interconnection; a second interconnection interconnecting the first interconnection; and a magnetoresistive effect element formed at an intersection of the first interconnection and the second interconnection, the magnetoresistive effective element including: a first ferromagnetic layer; a nonmagnetic layer formed on the first ferromagnetic layer; a second ferromagnetic layer formed on the nonmagnetic layer; and a sidewall insulating film formed on a side wall of the second ferromagnetic layer, an end of the first ferromagnetic layer being aligned with an end of the sidewall insulating film.

According to the present invention, in forming a magnetoresistive effect element including a first ferromagnetic layer, nonmagnetic layer and a second ferromagnetic layer laid one on the other, the nonmagnetic layer and the first ferromagnetic layer are patterned by using as the mask the sidewall insulating film formed on the side wall of the second ferromagnetic layer, whereby the disalignment between the first ferromagnetic layer and the second ferromagnetic layer can be prevented. Thus, the erroneous writing and erroneous reading due to the fluctuation of the leakage magnetic field from the first ferromagnetic layer can be suppressed. The fluctuation of the leakage magnetic field can be suppressed, which allows the horizontal distance between the end of the first ferromagnetic layer and the end of the second ferromagnetic layer to be small, and accordingly high integration can be realized. A magnetic memory device can comprise such magnetoresistive effect element, whereby the magnetic memory device can have high fabricating yield and high reliability.

### BRIEF DESCRIPTION OF THE DRAWINGS

FIG. 1 is a plan view showing the structure of the magnetic memory device according to one embodiment of the present invention.

FIG. 2 is a diagrammatic sectional view showing the structure of the magnetic memory device according to the embodiment of the present invention.

FIGS. 3A-3C, 4A-4B, 5A-5B, 6A-6B, 7A-7B, 8A-8B, 9A-9B are sectional views showing the method for fabricating the magnetic memory device according to the embodiment of the present invention.

FIGS. 10A and 10B are diagrammatic sectional views showing the structure of the conventional magnetoresistive effect element.

### DETAILED DESCRIPTION OF THE PREFERRED EMBODIMENTS

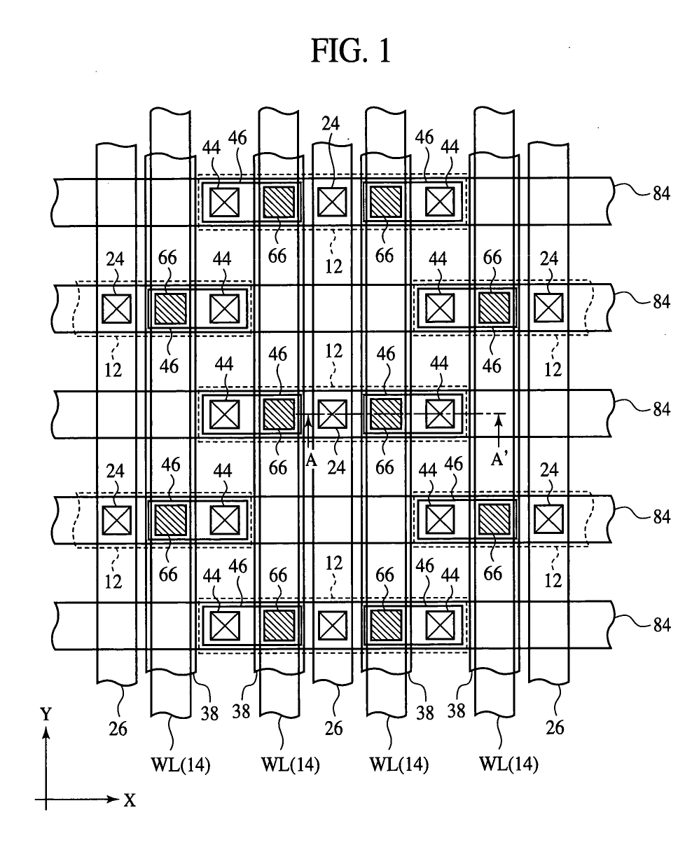

The magnetic memory device and the method for fabricating the same according to one embodiment of the present invention will be explained with reference to FIGS. 1 to 9B.

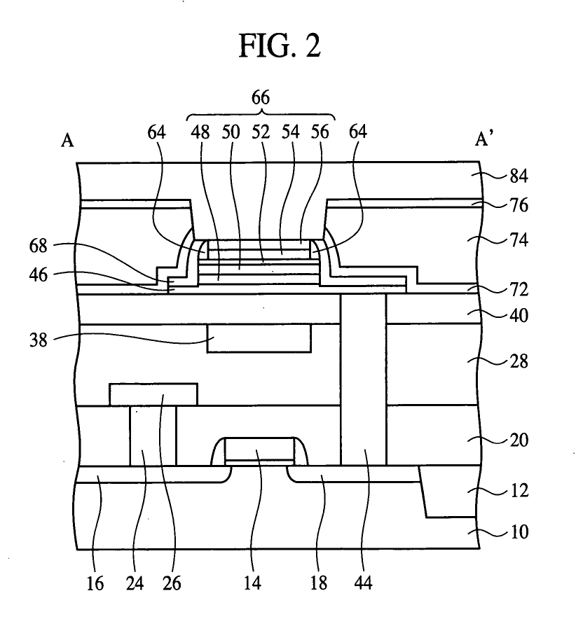

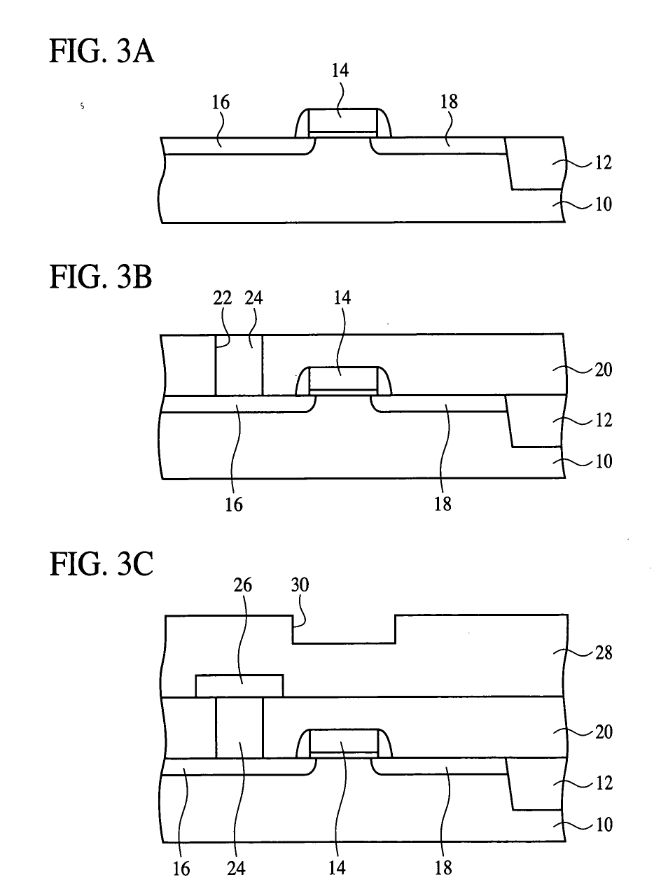

FIG. 1 is a plan view showing the structure of the magnetic memory device according to the present embodiment. FIG. 2 is a diagrammatic sectional view showing the structure of the magnetic memory device according to the present embodiment. FIGS. 3A to 9B are sectional views showing the method for fabricating the magnetic memory device according to the present embodiment.

First, the structure of the magnetic memory device according to the present embodiment will be explained with reference to FIGS. 1 and 2. FIG. 2 is the sectional view along the line A-A′ in FIG. 1.

A device isolation film 12 for defining a plurality of active regions is formed on a silicon substrate 10. The respective active regions have a rectangular shape which is elongated in the X-direction and are arranged in zigzag.

On the silicon substrate 10 with the device isolation film 12 formed on, word lines WL are formed, extended in the Y-direction. The word lines WL are extended by two in each active region. Source/drain regions 16, 18 are respectively formed in the active region on both sides of the word lines WL. Thus, two selection transistors each including the gate electrode 14 formed of the word line WL and the source/drain regions 16, 18 are formed in each active region. The two selection transistors formed on each active region include the source/drain region 16 in common.

An inter-layer insulating film 20 is formed on the silicon substrate 10 with the selection transistors formed on. A contact plug 24 is buried in the inter-layer insulating film 20, connected to the source/drain region 16. A ground line 26 is formed on the inter-layer insulating film 20, electrically connected to the source/drain region 16 via the contact plug 24.

An inter-layer insulating film 28 is formed on the inter-layer insulating film 20 with the ground line 26 formed on. A write word line 38 is buried in the inter-layer insulating film 28. The write word line 38 is formed over the gate electrode 14.

An inter-layer insulating film 40 is formed on the inter-layer insulating film 28 with the write word line 38 buried in. A contact plug 44 is buried in the inter-layer insulating films 40, 28, 20. On the inter-layer insulating film 40 with the contact plug 44 buried in, a lower electrode layer 46 electrically connected to the source/drain region 18 via the contact plug 44 is formed on the inter-layer insulating film 40 with the contact plug 44 buried in.

An MTJ element 66 including an anti-ferromagnetic layer 48, a pinned magnetic layer 50 (a first ferromagnetic layer), a tunnel insulating film 52 (nonmagnetic layer), a free magnetic layer 54 (a second ferromagnetic layer) and a cap layer 56 is formed on the lower electrode 46. A sidewall insulating film 64 is formed on the side walls of the cap layer 56 and the free magnetic layer 54, and the tunnel insulating film 52, the pinned magnetic layer 50 and the anti-ferromagnetic layer 48 are patterned in alignment with the sidewall insulating film 64.

On the inter-layer insulating film 40 with the lower electrode 46 and the MTJ element 66 formed on, insulating films 68, 72, 74, 76, 78 are formed. A via hole 80 is formed in the insulating films 68, 72, 74, 76, and an interconnection trench 82 extended in the X-direction is formed in the insulating film 78. In the interconnection trench 82, a bit line 84 is buried, connected to the MTJ element 66 through the via hole 80.

Thus, the magnetic memory device including the memory cells of the 1T-1MTJ type each including one selection transistor and one MTJ element is constituted.

Here, as shown in FIG. 2, the MTJ element 66 of the magnetic memory device according to the present embodiment includes the sidewall insulating film 64 formed on the side wall of the free magnetic layer 54. The pinned magnetic layer 50 is formed in alignment with the free magnetic layer 54 and the sidewall insulating film 64.

Thus, the horizontal distance between the end of the free magnetic layer and the end of the pinned magnetic layer can be suitably controlled by the film thickness of the sidewall insulating film 64. Thus, the fabrication fluctuation can be much decreased.

The pinned magnetic layer 50 is formed by self-alignment with the free magnetic layer 54, whereby erroneous writing and erroneous reading due to fluctuation of the leakage magnetic field caused by the disalignment between the pinned magnetic layer 50 and the free magnetic layer 54 can be prevented.

The side wall of the free magnetic layer 54 is covered by the sidewall insulating film 64 when the pinned magnetic layer 50 is patterned, whereby the electric short-circuit between the free magnetic layer 54 and the pinned magnetic layer 50 due to objects adhering to the side wall in the patterning can be prevented. Thus, the fabrication yield can be improved.

Next, the method for fabricating the magnetic memory device according to the present embodiment will be explained with reference to FIGS. 3A to 9B.

First, the device isolation film 12 is formed on the silicon substrate 10 by, e.g., STI (Shallow Trench Isolation) method.

Then, in each active region defined by the device isolation film 12, the selection transistor including the gate electrode 14 and the source/drain regions 16, 18 is formed in the same way as in the usual MOS transistor fabricating method (FIG. 3A).

Next, on the silicon substrate 10 with the selection transistor formed on, a silicon oxide film is deposited by, e.g., CVD method, and the surface of the silicon oxide film is planarized by CMP method to form the inter-layer insulating film 20 of the silicon oxide film.

Next, the contact hole 22 is formed in the inter-layer insulating film 20 down to the source/drain region 16 by photolithography and dry etching.

Next, a titanium nitride film as a barrier metal and a tungsten film are deposited by, e.g., CVD method, and then these conductive films are etched back or polished back to form the contact plug 24 buried in the contact hole 22 and electrically connected to the source/drain region 16 (FIG. 3B).

Then, a conductive film is deposited on the inter-layer insulating film 20 with the contact plug 24 buried in and patterned to form the ground line 26 electrically connected to the source/drain region 16 via the contact plug 24.

Next, a silicon oxide film is deposited by, e.g., CVD method on the inter-layer insulating film 20 with the ground line 26 formed on, and the surface of the silicon oxide film is planarized by CMP method to form the inter-layer insulating film 28 of the silicon oxide film.

Then, the interconnection trench 30 for the write word line to be buried in is formed in the inter-layer insulating film 28 by photolithography and etching (FIG. 3C). The depth of the interconnection trench 30 is, e.g., about 200˜300 nm.

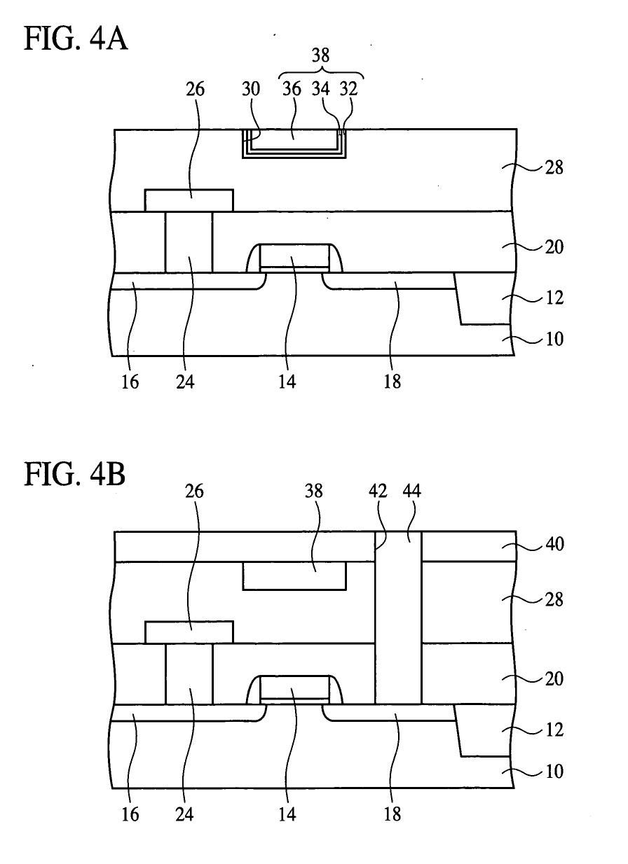

Next, a Ta film 32 and an NiFe film 34, and a Cu film 36 are deposited respectively by, e.g., sputtering method and by, e.g., electrolytic plating method, and then these conduction films are planarized by CMP method to form the write word line 38 buried in the interconnection trench (FIG. 4A). The write word line 38 may have the yoke structure as shown or the usual interconnection structure used in the conventional silicon process.

Next, on the inter-layer insulating film 28 with the write word line 38 buried in, a silicon nitride film of, e.g., a 10˜20 nm-thick and a silicon oxide film of a 20˜500 nm-thick are deposited by, e.g., CVD method, and the surface of the silicon oxide film is planarized by CMP method to form the inter-layer insulating film 40 of the layer film of the silicon nitride film and the silicon oxide film. The inter-layer insulating film 40 is set at a film thickness which permits a required inversion magnetic field (about 20˜200 Oe) to be applied when a prescribed writing current is flowed to the write word line 38.

Then, by photolithography and dry etching, the contact hole 42 is formed in the inter-layer insulating films 40, 28, 20 down to the source/drain region 18.

Next, a titanium nitride film as the barrier metal and a tungsten film are deposited by, e.g., CVD method and are etched back or polished back to form the contact plug 44 buried in the contact hole 42 and electrically connected to the source/drain region 18 (FIG. 4B).

Then, a Ta film of, e.g., a 20˜100 nm-thick is deposited by, e.g., sputtering method to form the lower electrode layer 46 of the Ta film.

Next, on the lower electrode layer 46, a 0˜5 nm-thick film of a soft magnetic material, such as NiCr, NiFe or others, e.g., an NiFe film of, e.g., a 2 nm-thick, and a 8˜30 nm-thick film of an anti-ferromagnetic material, such as PtMn, IrMn, PdPtMn or others, e.g., a PtMn film of, e.g., a 15 nm-thick are deposited by, e.g., sputtering method to form the anti-ferromagnetic layer 48 of the layer film of the NiFe film as the base film and the PtMn film.

Then, on the anti-ferromagnetic layer 48, a 1˜10 nm-thick film of a ferromagnetic material, such as Co, CoFe or others, e.g., a 3 nm-thick CoFe film, a 0.1˜3 nm-thick film of a nonmagnetic material, such as Ru, Rh or others, e.g., a 0.8 nm-thick Ru film, and a 1˜10 nm-thick film of a ferromagnetic material, such as Co, CoFe or others, e.g., a 3 nm-thick CoFe film are deposited to form the pinned magnetic layer 50 of the multilayered ferri-structure.

Then, a 0.1˜10 nm-thick insulating material, such as AlO, TiO, MgO, TaO or others, e.g., a 0.85 nm-thick alumina (Al₂O₃) film are formed on the pinned magnetic layer 50 by, e.g., sputtering method to form the tunnel insulating film 52 of the alumina film.

Then, a 0.5˜5 nm-thick film of a soft magnetic material, such as CoFe, CoFeB or others, e.g., a 2 nm-thick CoFe film and a 1˜10 nm-thick film of a soft magnetic material, such as NiFe, Ta/NiFe, Ti/NiFe or others, e.g., a 4 nm-thick NiFe film are deposited on the tunnel insulating film 52 by, e.g., sputtering method to form the free magnetic layer 54 of the layer film of the CoFe film and the NiFe film.

Next, a 1˜20 nm-thick Ru film of, e.g., a 10 nm-thick and a 10˜200 nm-thick Ta film of, e.g., a 30 nm-thick are deposited on the free magnetic layer 54 by, e.g., sputtering method to form the cap layer 56 of the layer film of the Ru film and the Ta film.

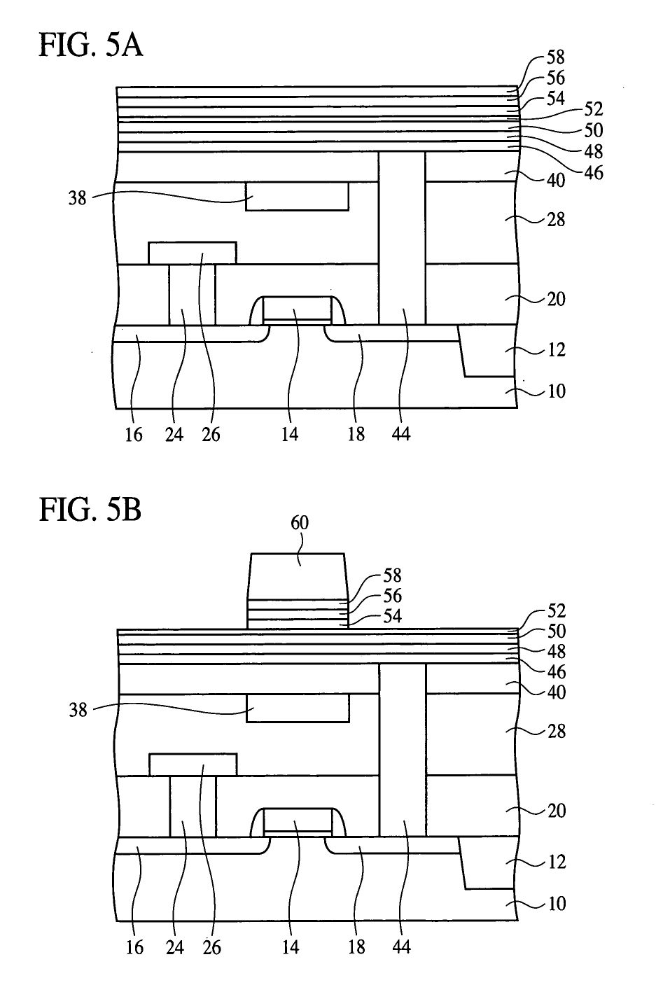

Then, an insulating material, such as SiN, Al₂O₃, SiON, SiC or others, e.g., a 0˜100 nm-thick SiN film is deposited on the cap layer 56 by, e.g., CVD method to form the cap insulating film 58 of the SiN film (FIG. 5A) The cap insulating film 58 functions as the hard mask in the later step of patterning the barrier insulating film 52, the pinned magnetic layer 50 and the antiferromagnetic layer 48 and is not essentially formed when the cap layer 56 alone is enough to function as the hard mask for this patterning step.

Then, a photoresist film 60 having the pattern of the free magnetic layer 54 to be formed is formed on the cap insulating film 58. The free magnetic layer 54 is patterned in, e.g., an about ˜100×200 nm size.

Then, with the photoresist film 60 as the mask, the cap insulating film 58, the cap layer 56 and the free magnetic layer 54 are anisotropically etched (FIG. 5B). The cap insulating film 58 and the cap layer 56 are etched with an etching gas of, e.g., CF₄/Ar=1:10 and under an internal chamber pressure of 10 Pa. The free magnetic layer 54 is etched with an etching gas of, e.g., CO/HNF₃=1:10 and under an internal chamber pressure of 10 Pa. This etching is stopped on the tunnel insulating film 52, based on the emission of Fe or others, the inductance change of a plasma source, mass spectroscopy or others.

Next, the photoresist film 60 is removed by, e.g., ashing.

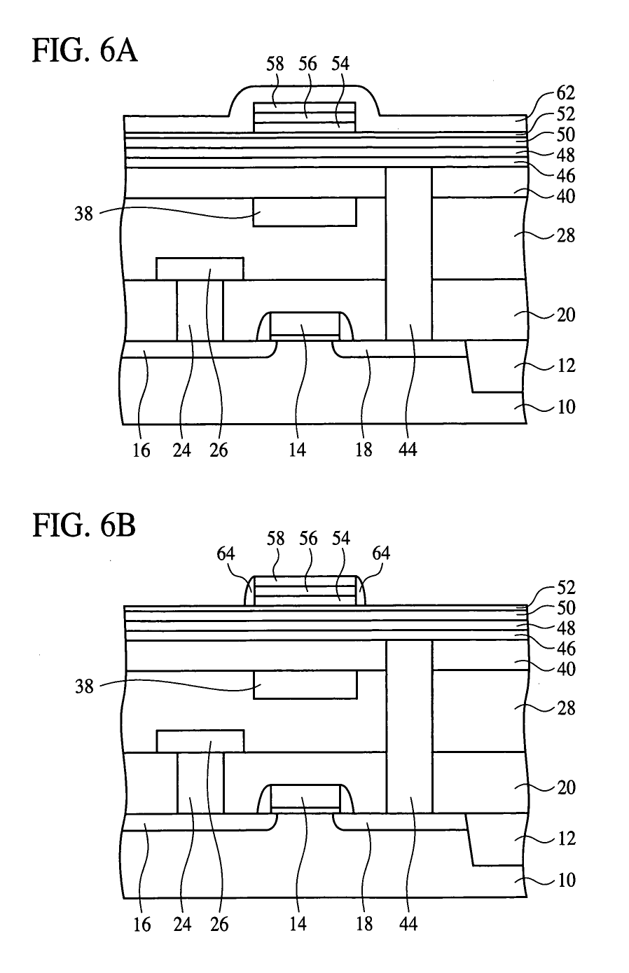

Next, a film of an insulation material, such as SiN, Al₂O₃, SiON, SiC or others, e.g., a 100˜200 nm-thick SiN film is deposited by, e.g., CVD method to form an insulating film 62 of the SiN film (FIG. 6A). Preferably, the insulating film 62 is formed of the same insulation material as the cap insulating film 58 or an insulation material having etching characteristics approximate to those of the cap insulating film 58. The insulating film 62 may be formed of a layer film of an insulating material and a conductive material, e.g., the layer film of Al₂O₃/poly-Si or others. The film thickness of the insulating film 62 is a design value of the projection of the pinned magnetic layer 50 beyond the free magnetic layer 54 (a horizontal distance between the end of the free magnetic layer and the end of the pinned magnetic layer 50 as complete).

Then, the insulating film 62 is anisotropically etched by dry etching until the tunnel insulating film 52 is exposed. Thus, the sidewall insulating film 64 of the insulating film 62 is formed on the side wall of the free magnetic layer 54, the cap layer 56 and the cap insulating film 58 (FIG. 6B). The SiN film 62 is etched with the etching gas of, e.g., CF₄/O₂/Ar, Cl₂/BCL₃/ Ar or others, and the etching is stopped on the tunnel insulating film 52, based on plasma emission and inductance changes.

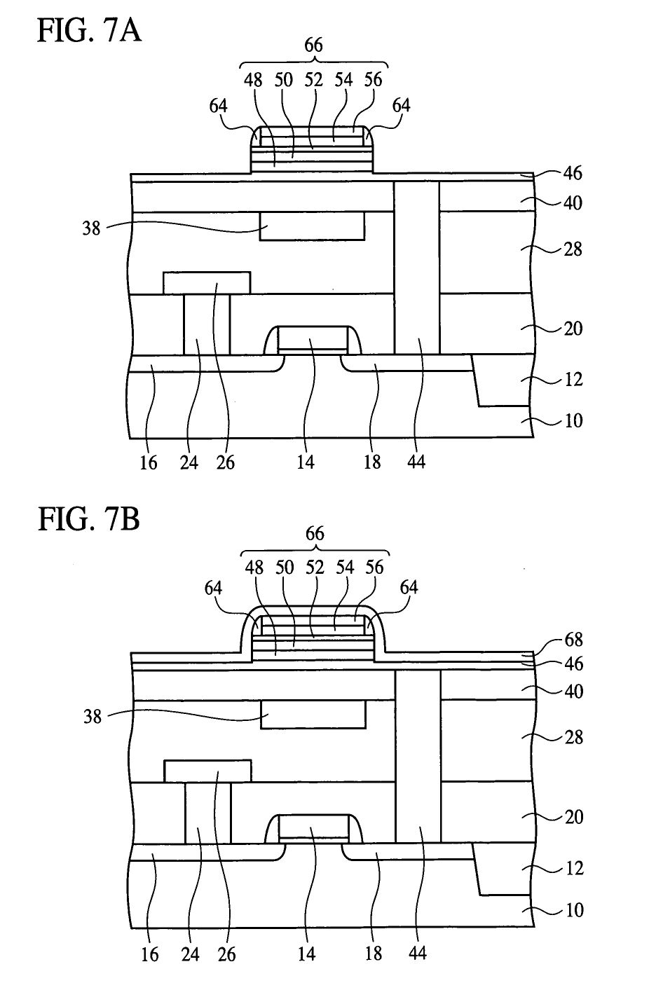

Next, with the cap insulating film 58 and the sidewall insulating film 64 as the hard mask, the tunnel insulating film 52, the pinned magnetic layer 50 and the anti-ferromagnetic layer 48 are anisotropically etched by dry etching (FIG. 7A). At this time, when the etching up to the anti-ferromagnetic layer 48 is completed, the thickness of the cap insulating film 58 and the thickness of the Ta film of the cap layer 56 are adjusted so that the upper surface and the side surface of the Ru film of the cap layer 56 are not exposed. Preferably, the cap insulating film 58 is completely removed by the time that the etching up to the anti-ferromagnetic layer 48 has been completed.

Thus, the pinned magnetic layer 50 and the anti-ferromagnetic layer are patterned, whereby the pinned magnetic layer 50 can be processed by self-alignment with the free magnetic layer 54. The horizontal distance between the end of the free magnetic layer 54 and the end of the pinned magnetic layer 50 is defined by the film thickness of the sidewall insulating film 64, whereby the fabrication fluctuation can be much decreased. The free magnetic layer 54 and the pinned magnetic layer 50 are separately patterned, whereby the electric short-circuit between the free magnetic layer 54 and the pinned magnetic layer 50 due to the adhesion of objects to the side wall generated in the patterning can be prevented. Thus, the fabrication yield can be improved.

Thus, the MTJ element 66 including the layer structure of the anti-ferromagnetic layer 48, the pinned magnetic layer 50, the tunnel insulation layer 52, the free magnetic layer 54 and the cap layer 56 can be formed (FIG. 7A).

Next, a film of an insulating material, such as SiO, SiN or others, e.g., a 50˜100 nm-thick silicon oxide film is deposited by, e.g., CVD method on the lower electrode layer 46 with the MTJ element 66 formed on to form the insulating film 68 of the silicon oxide film (FIG. 7B). The insulating film 68 is for protecting the MTJ element 66 from plasmas in processing the lower electrode layer 46.

Then, a photoresist film 70 having a pattern of the lower electrode layer 46 to be formed is formed on the insulating film 68 by photolithography.

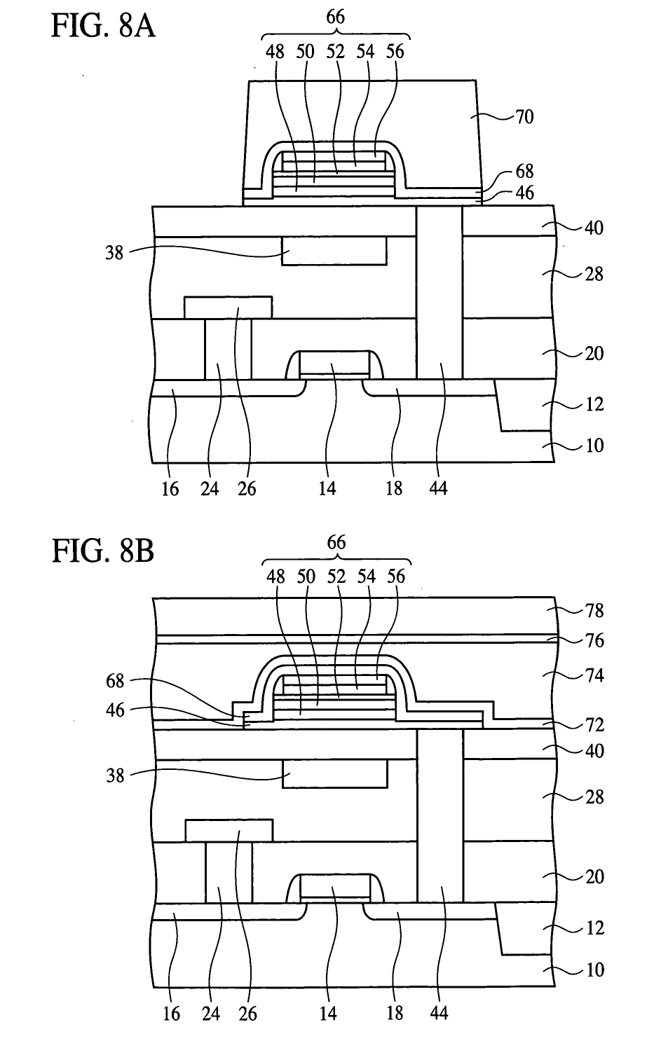

Then, with the photoresist film 70 as the mask, the insulating film 68 and the lower electrode layer 46 are anisotropically etched. Thus, the lower electrode layer 46 electrically connecting the MTJ element 66 to the source/drain diffused layer 18 via the contact plug 44 is formed (FIG. 8A).

Next, the photoresist film 70 is removed by, e.g., ashing.

Then, the insulating film 72 of, e.g., an SiN film and the insulating film 74 of, e.g., a silicon oxide film are formed on the entire surface by, e.g., CVD method.

Next, the surface of the insulating film 74 is planarized by, e.g., CMP method.

Then, on the insulating film 74 having the surface planarized, the insulating film 76 of, e.g., an SiN film and the insulating film 78 of, e.g., a silicon oxide film are formed by, e.g., CVD method.

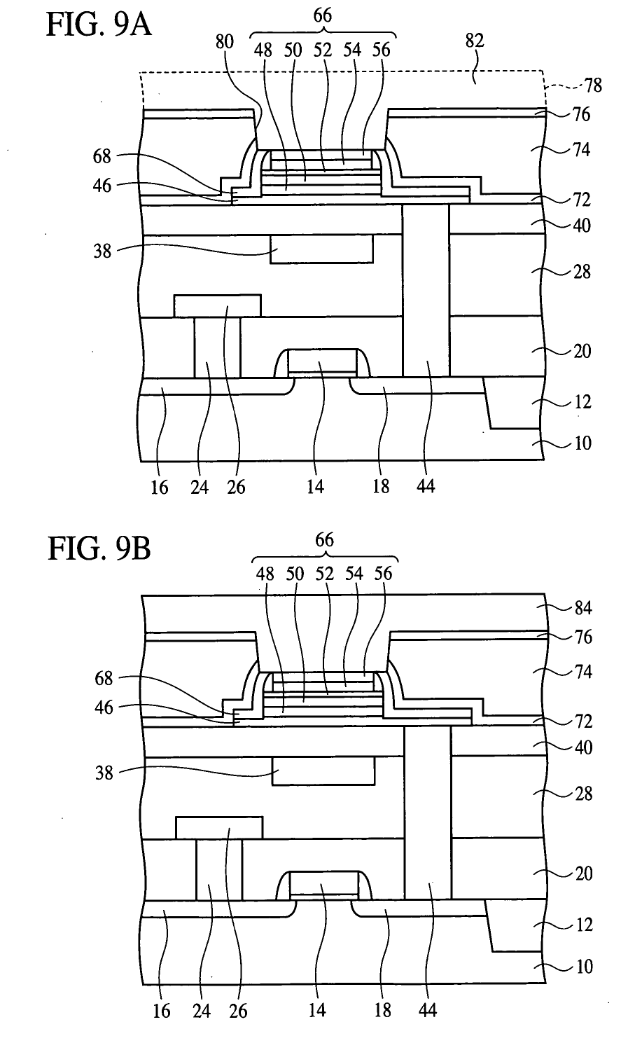

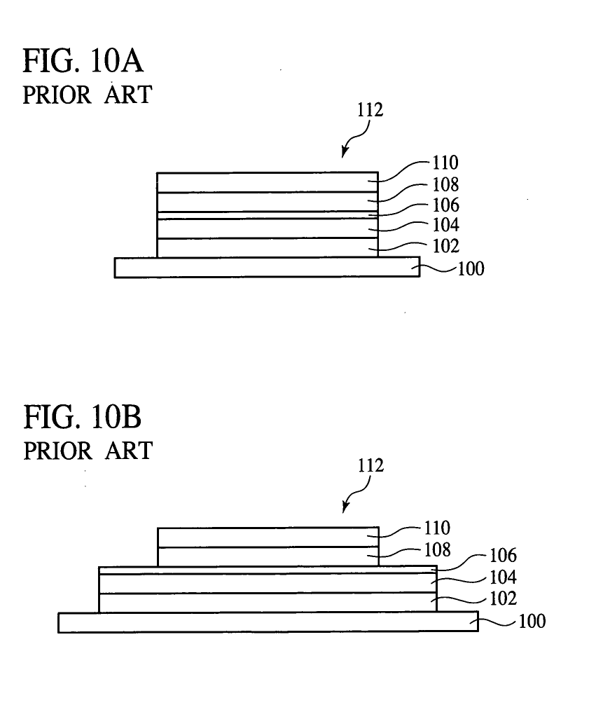

Then, in the same way as in the usual dual damascene process, the via hole 80 is formed in the insulating films 68, 72, 74, 76, and the interconnection trench 82 is formed in the insulating film 78 (FIG. 9A). At this time, the sidewall insulating film 64 formed on the side wall of the cap layer 56 and the free magnetic layer 54 can prevent the via hole 80 from being opened on the pinned magnetic layer 50 even when disalignment takes place. Thus, the alignment margin can be large.

Then, the barrier film (not shown) of a TaN film or others and a Cu film (not shown) are deposited on the entire surface, and these conductive films are polished until the surface of the insulating film 78 is exposed to form the bit line 84 buried in the interconnection groove 82 and electrically connected to the MTJ element 66 via the via hole 80 (FIG. 9B).

Then, insulating layers, interconnection layers, etc. are formed further thereon as required, and the magnetic memory device is completed.

As described above, according to the present embodiment, when the magnetoresistive effect element including the layer structure of the pinned magnetic layer, the tunnel insulating film and the free magnetic layer is formed, the tunnel insulating film and the pinned magnetic layer are patterned by using as the mask the sidewall insulating film formed on the side wall of the free magnetic layer, whereby the disalignment between the pinned magnetic layer and the free magnetic layer can be prevented. Thus, the erroneous writing and erroneous reading due to the fluctuation of the leakage magnetic field from the pinned magnetic layer can be suppressed. The fluctuation of the leakage magnetic field can be suppressed, which allows the horizontal distance between the end of the pinned magnetic layer and the end of the free magnetic layer to be small, and accordingly high integration can be realized. The magnetic memory device comprises such magnetoresistive effect element, whereby the magnetic memory device of high fabrication yield and high reliability can be provided.

### Modified Embodiments

The present invention is not limited to the above-described embodiments and can cover other various modifications.

For example, in the above-described embodiment, the present invention is applied to the magnetic memory device of the current drive-type which drives an MTJ elements by a magnetic field generated by flowing current to the signal line. However, the present invention is similarly applicable to the magnetic memory device of the spin injection-type which drives the magnetoresistive effect element by injecting spins. In the spin injection-type magnetic memory device, it is not necessary to form the write word line 38 of the above-described embodiment.

In the above-described embodiment, the pinned magnetic layer 50 has the multilayered ferri-structure of CoFe/Ru/CoFe to thereby decrease the leakage magnetic field from the pinned magnetic layer 50. However, the pinned magnetic layer may have the single layer structure of, e.g., CoFe film. The effect of preventing the influence of the leakage magnetic field due to the fabrication fluctuation, which is characteristic of the present invention, can be achieved irrespective of the structure of the pinned magnetic layer 50.

In the present embodiment, the free magnetic layer 54 has the layer structure of NiFe/CoFe but may have the single-layer structure of NiFe or others. The free magnetic layer 54 may have the multilayered ferri-structure of, e.g., CoFe/Ru/NiFe, CoFe/Rh/NiFe or others.

In the above-described embodiment, the present invention is applied to the magnetic memory device of 1T-1MT-type, in which one selection transistor and one MTJ element form one memory cell. However, the memory cell is not limited to this constitution. For example, the present invention is applicable to magnetic memory device of 2T-2MTJ type and magnetic memory device of 1T-2MTJ type.

In the above-described embodiment, the magnetoresistive effect element is an MTJ element. However, the present invention is applicable widely to magnetoresistive effect elements utilizing resistance changes based on relationships of spins between the magnetic layers. For example, the present invention is also applicable to magnetoresistive effect elements including two magnetic layers laid one on the other with a conductive non-magnetic layer formed therebetween.

In the above-described embodiment, the magnetoresistive effect element according to the present invention is applied to the magnetic memory device. However, the present invention may be applied to other devices using magnetoresistive effect elements, e.g., magnetic heads, etc.

What is claimed is:

1. A magnetoresistive effect element comprising:
a first ferromagnetic layer;
a nonmagnetic layer formed on the first ferromagnetic layer;
a second ferromagnetic layer formed on the nonmagnetic layer; and
a sidewall insulating film formed on a side wall of the second ferromagnetic layer,
an end of the first ferromagnetic layer being aligned with an end of the sidewall insulating film.

2. A magnetoresistive effect element according to claim 1, which further comprises
an anti-ferromagnetic layer formed below the first ferromagnetic layer, for pinning a magnetization direction of the first ferromagnetic layer, and in which an end of the anti-ferromagnetic layer is aligned with the end of the sidewall insulating film.

3. A magnetoresistive effect element according to claim 1, which further comprises
a cap layer of a nonmagnetic material formed on the second ferromagnetic layer, and in which
the sidewall insulating film is formed on a side wall of the cap layer.

4. A magnetoresistive effect element according to claim 3, wherein
the cap layer includes a first cap layer of a conductive material formed on the second ferromagnetic layer.

5. A magnetoresistive effect element according to claim 4, wherein
the cap layer further includes a second cap layer of an insulating material formed on the first cap layer.

6. A magnetoresistive effect element according to claim 5, wherein
the second cap layer and the sidewall insulating film have substantially the same etching characteristics.

7. A magnetoresistive effect element according to claim 1, wherein
the nonmagnetic layer is a tunnel insulating film.

8. A method for fabricating a magnetoresistive effect element comprising the steps of:
forming a first ferromagnetic layer;
forming a nonmagnetic layer on the first ferromagnetic layer;
forming a second ferromagnetic layer on the nonmagnetic layer;
forming a cap layer of a nonmagnetic material on the second ferromagnetic layer;
patterning the cap layer and the second ferromagnetic layer into a prescribed configuration;
forming a sidewall insulating film on the side wall of the patterned cap layer and second ferromagnetic layer; and
patterning the nonmagnetic layer and the first ferromagnetic layer with the cap layer and the sidewall insulating film as the mask.

9. A method for fabricating a magnetoresistive effect element according to claim 8, wherein
in the step of forming a cap layer, a first cap layer of a conductive material formed on the second ferromagnetic layer and a second cap layer of an insulating material formed on the first cap layer are formed.

10. A method for fabricating a magnetoresistive effect element according to claim 9, wherein
the film thickness of the second cap layer is so set that the second cap layer becomes absent when the step of patterning the nonmagnetic layer and the first ferromagnetic layer is completed.

11. A method for fabricating a magnetoresistive effect element according to claim 9, wherein
the second cap layer and the sidewall insulating film have substantially the same etching characteristics.

12. A method for fabricating a magnetoresistive effect element according to claim 8, which further comprises before the step of forming the first ferromagnetic layer the step of:
forming an anti-ferromagnetic layer for pinning a magnetization direction of the first ferromagnetic layer, and in which
in the step of patterning the nonmagnetic layer and the first ferromagnetic layer, the anti-ferromagnetic layer is also patterned.

13. A method for fabricating a magnetoresistive effect element according to claim 8, wherein
the nonmagnetic layer is a tunnel insulating film of an insulating material.

14. A magnetic memory device comprising:
a first interconnection;
a second interconnection interconnecting the first interconnection; and
a magnetoresistive effect element formed at an intersection of the first interconnection and the second interconnection,
the magnetoresistive effective element including:
a first ferromagnetic layer;
a nonmagnetic layer formed on the first ferromagnetic layer;
a second ferromagnetic layer formed on the nonmagnetic layer; and
a sidewall insulating film formed on a side wall of the second ferromagnetic layer,
an end of the first ferromagnetic layer being aligned with an end of the sidewall insulating film.
